(19) United States
(12) Patent Application Publication
(10) Pub. No.: US 2020/0401002 A1
(43) Pub. Date: Dec. 24, 2020

(54) ANTISTATIC DISPLAY PANEL AND MANUFACTURING METHOD THEREOF

(71) Applicant: WUHAN CHINA STAROPOELECTRONICSTECHNOLOGYCO.,LTD, Wuhan,Hubei (CN)

(72) Inventor: Gaiping LU, Wuhan, Hubei (CN)

(21) Appl. No.: 16/469,160

(22) PCT Filed: Apr. 9, 2019
(86) PCT No.: PCT/CN2019/081836

§ 371 Date: Jun. 13, 2019

(30) Foreign Application Priority Data
Dec. 27, 2018 (CN) 20181165682.1

(51) Int. Cl. G02F 1/1362; H05F 3/00; H05K 1/18; G02F 1/1368

(52) U.S. Cl. CPC G02F 1/136204; H05F 3/00; H05K 2201/10136; G02F 1/1368; G02F 2202/22; H05K 1/189

(57) ABSTRACT

An antistatic display panel and a manufacturing method thereof are provided. The antistatic display panel includes a display area, a flexible circuit board, a driving chip, and an electrostatic discharge circuit. The driving chip is fixed on a surface of the flexible circuit board and is bound to a lower edge of the display area. A plurality of pins of the driving chip are electrically connected to the electrostatic discharge circuit, and the pins form a closed loop with the electrostatic discharge circuit.

### FIELD OF INVENTION

The present disclosure relates to the field of display technologies, and especially, to an antistatic display panel and manufacturing method thereof.

### BACKGROUND OF INVENTION

As mobile display technologies advanced to higher image quality, higher definition, thinner, and lower power consumption, display panels need to be cut from large glass into small display panels. Because a large amount of static electricity is easily generated during the cutting process, static electricity is easily conducted into peripheral metal wires of a liquid crystal panel, and a display area thereof. This causes electrostatic damage to components, thereby causing display abnormality and greatly affecting defect-free rate. Conventional chip on glass (COG) products conduct with electrostatic protection design. However, as a frame is shrinking, a displayable area is increased, causing a conventional electrostatic protection design cannot be set. A graphic design of a narrow bezel panel is closer to a cutting line, therefore, an electrostatic protection of a narrow bezel needs to be strengthened.

In summary, the conventional narrow bezel display panel cannot be set the electrostatic protection design during the design process. The static electricity is easily conducted into the metal wires on the periphery of the display panel, and the display area. This causes electrostatic damage to the components, and further affects product quality.

### SUMMARY OF INVENTION

The present disclosure provides an antistatic display panel and manufacturing method thereof. In the present display panel, since the electrostatic protection design cannot be set on the conventional narrow bezel display panel during the design process, causing the static electricity is easily conducted into the metal wires on the periphery of the display panel, and the display area. This causes electrostatic damage to the components, and further affects product quality. The present disclosure can protect a narrow bezel display panel from electrostatic damage.

In order to solve the above issues, technical solution provided in the present disclosure are as follows:

The present disclosure provides an antistatic display panel including a display area, a flexible circuit board, a driving chip and an electrostatic discharge circuit. The driving chip is fixed on a surface of the flexible circuit board and is bound to a lower edge of the display area; wherein a plurality of pins of the driving chip are electrically connected to the electrostatic discharge circuit, and the pins form a closed loop with the electrostatic discharge circuit.

In the antistatic display panel provided by the embodiment of the present disclosure, the electrostatic discharge circuit is composed of two or more shorting bars and metal wires.

In the antistatic display panel provided by the embodiment of the present disclosure, a first end of each of the shorting bars is electrically connected to a corresponding one of the pins, and a second end of each of the shorting bars is electrically connected to the metal wires.

In the antistatic display panel provided by the embodiment of the present disclosure, the driving chip is disposed along a first direction D1, each of the shorting bars is disposed perpendicular to the first direction D1, and every two adjacent shorting bars are provided with equal distance.

In the antistatic display panel provided by the embodiment of the present disclosure, each of the pins includes a chip input pin and a chip output pin, the chip input pin is electrically connected to a corresponding one of the shorting bars, the chip output pin is electrically connected to another corresponding one of the shorting bars.

The present disclosure further provides a method of manufacturing an antistatic display panel, including:

S10, providing a thin film transistor (TFT) array substrate, wherein the TFT array substrate comprises a display area, and a flexible circuit board is bound along a first direction D1 near a lower edge of the display area, and the flexible circuit board is fixed with a driving chip;

S20, providing an electrostatic discharge circuit, wherein a plurality of pins of the driving chip are electrically connected to the electrostatic discharge circuit, the pins and the electrostatic discharge circuit form a closed loop, and the electrostatic discharge circuit comprises two or more shorting bars and metal wires, the shorting bars are disposed perpendicular to the first direction D1, and every two adjacent shorting bars are provided with equal distance;

S30, providing a cutting line enclosing a rectangular frame on the TFT array substrate, wherein the cutting line passes through the electrostatic discharge circuit along the first direction D1, and the TFT array substrate is cut along the cutting line using a cutter, and the electrostatic discharge circuit is disconnected to obtain the antistatic display panel.

In the manufacturing method of the antistatic display panel provided by the embodiment of the present disclosure, a first end of each of the shorting bars is electrically connected to a corresponding one of the pins, and a second end of each of the shorting bars is electrically connected to the metal wires.

In the manufacturing method of the antistatic display panel provided by the embodiment of the present disclosure, in the S30, the cutting line comprises a first sub-cut line, a second sub-cut line, a third sub-cut line, and a fourth a sub-cut line, the first sub-cut line and the third sub-cut line are arranged in parallel along the first direction D1, and the second sub-cut line and the fourth sub-cut line are arranged in parallel along a direction perpendicular to the first direction D1.

In the manufacturing method of the antistatic display panel provided by the embodiment of the present disclosure, the third sub-cut line passes through the shorting bars.

The present disclosure further provides a method of manufacturing an antistatic display panel, including:

S10, providing a TFT array substrate, the TFT array substrate comprises a display area, and a flexible circuit board is bound along a first direction D1 near a lower edge of the display area, and the flexible circuit board is fixed with a driving chip;

S20, providing an electrostatic discharge circuit, wherein a plurality of pins of the driving chip are electrically connected to the electrostatic discharge circuit;

S30, providing a cutting line enclosing a rectangular frame on the TFT array substrate, wherein the cutting line passes through the electrostatic discharge circuit along the first direction D1, and the TFT array substrate is cut along the cutting line using a cutter, and the electrostatic discharge circuit is disconnected to obtain the antistatic display panel.

In the method of manufacturing the antistatic display panel provided by the embodiment of the present disclosure, in the S30, the cutting line comprises a first sub-cut line, a second sub-cut line, a third sub-cut line, and a fourth a sub-cut line, the first sub-cut line and the third sub-cut line are arranged in parallel along the first direction D1, and the second sub-cut line and the fourth sub-cut line are arranged in parallel along a direction perpendicular to the first direction D1.

In the method for manufacturing the antistatic display panel provided by the embodiment of the present disclosure, the third sub-cut line passes through the shorting bars.

The present disclosure has the beneficial effects that: the anti-static display panel and the manufacturing method provided by the present disclosure, providing a plurality of pins of the driving chip form a closed loop with the electrostatic discharge circuit, thereby effectively protecting the internal signal lines of the narrow bezel display panel. Further reducing the risk of electrostatic damage to the display panel, and improving product defect-free rate.

### DESCRIPTION OF DRAWINGS

The accompanying figures to be used in the description of embodiments of the present disclosure or prior art will be described in brief to more clearly illustrate the technical solutions of the embodiments or the prior art. Obviously, the accompanying figures described below are only part of the embodiments of the present disclosure, from which figures those skilled in the art can derive further figures without making any inventive efforts.

FIG. 1 is a top view diagram of antistatic display panel according to an embodiment of the present disclosure.

FIG. 2 is an enlarged schematic diagram of a portion A in FIG. 1.

FIG. 3 is a schematic diagram showing the cutting of the antistatic display panel according to an embodiment of the present disclosure.

FIG. 4 is a flowchart diagram of the manufacturing method of the antistatic display panel according to an embodiment of the present disclosure.

FIG. 4A to FIG. 4C are schematic diagrams of manufacturing method of the antistatic display panel according to an embodiment of the present disclosures.

### DETAILED DESCRIPTION OF PREFERRED EMBODIMENTS

The following description of the various embodiments is provided to illustrate the specific embodiments. Directional terms described by the present disclosure, such as top, bottom, front, back, left, right, inner, outer, side, etc., are only directions by referring to the accompanying drawings, and thus the used terms are used only for the purpose of describing embodiments of the present disclosure and are not intended to be limiting of the present disclosure. In the drawings, units with similar structures are labeled with the same reference number.

The present disclosure is especially to the existing narrow bezel display panel. Because the electrostatic protection design cannot be set on the existing narrow bezel display panel during the design process, causing the static electricity is easily conducted into the metal wires on the periphery of the display panel, and the display area. Causing electrostatic damage on the device, further affecting product quality. This embodiment can solve the above issues.

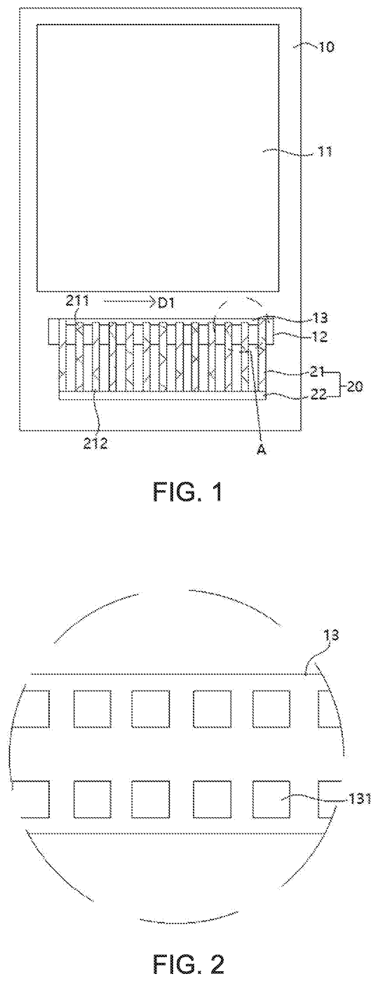

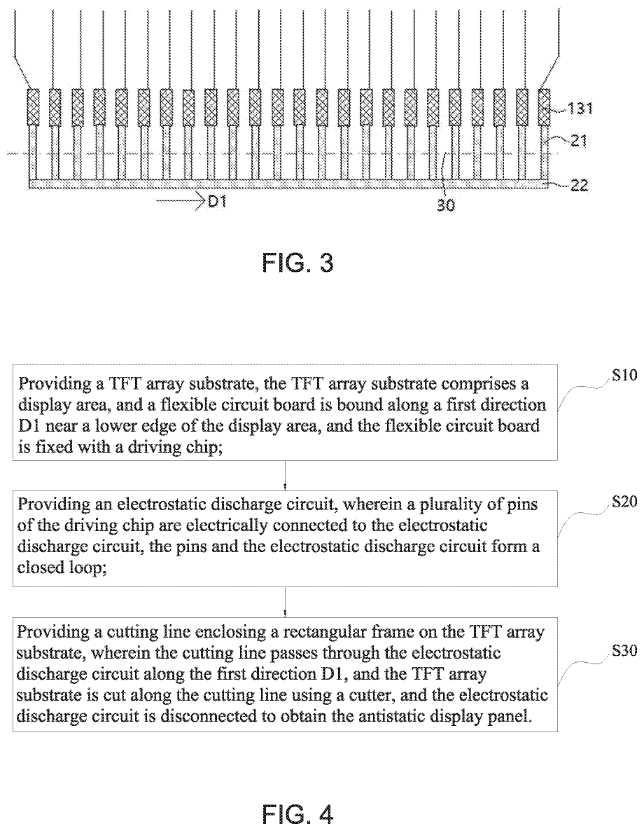

As illustrated in FIG. 1 and FIG. 2, which are top view diagrams of antistatic display panel according to an embodiment of the present disclosure.

Specifically, an embodiment of the present disclosure provides an antistatic display panel 10 including a display area 11, a flexible circuit board, a driving chip, and an electrostatic discharge circuit 20. The driving chip 13 is fixed on a surface of a flexible circuit board 12 and is bound near a lower edge of the display area 11.

A plurality of pins 131 of the driving chip 13 are electrically connected to the electrostatic discharge circuit 20, and the pins 131 form a closed loop with the electrostatic discharge circuit 20.

Specifically, the electrostatic discharge circuit 20 is composed of two or more shorting bars 21 and metal wires 22.

Specifically, a first end 211 of each of the shorting bars 21 is electrically connected to the corresponding one of pins 131, and a second end 212 of each of the shorting bars 21 is electrically connected to the metal wires 22.

Specifically, the driving chip 13 is disposed along the first direction D1, each of the shorting bar 21 is disposed perpendicular to the first direction D1, and every two adjacent shorting bars 21 are provided with equal distance.

Specifically, each of the pins 131 includes a chip input pin and a chip output pin, the chip input pin is electrically connected to a corresponding one of the shorting bars 21, the chip output pin is electrically connected to another corresponding one of the shorting bars 21.

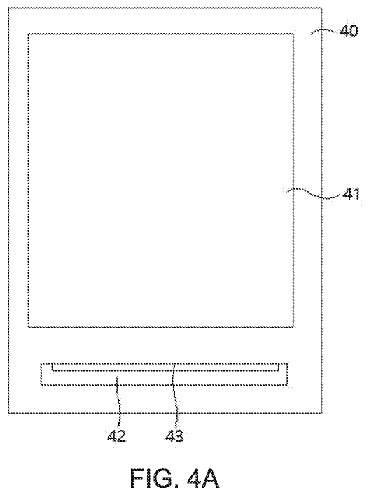

As illustrated in FIG. 3, a schematic diagram showing the cutting of the antistatic display panel according to an embodiment of the present disclosure is provided. The cutting line 30 passes through the shorting bars 21 along the first direction D1.

Because during the cutting process, a large amount of static electricity is easily generated, and pins 131 of the driving chip 13 are easy to attract static electricity. Pins 131 conduct the attracted static electricity into the electrostatic discharge circuit 20, and when the panel is cut, the shorting bars 21 are disconnected with the adjacent pins 131 to ensure subsequent modules normal use. Therefore, this effective protects the internal signal line of the narrow bezel display panel.

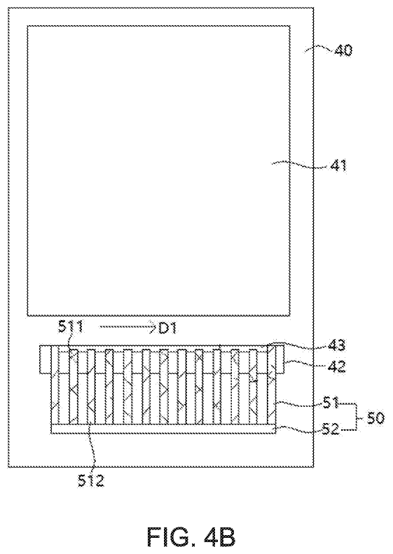

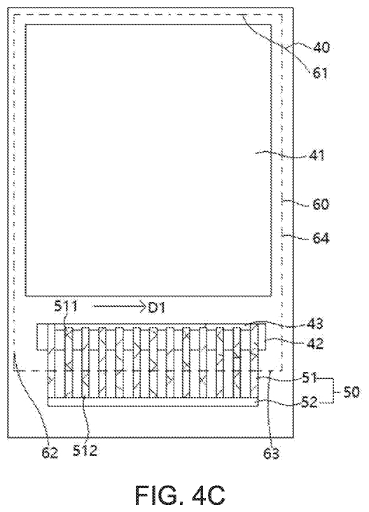

As shown in FIG. 4, an embodiment of the present disclosure further provides a method of manufacturing an antistatic display panel, including:

S10, providing a thin film transistor (TFT) array substrate 40, wherein the TFT array substrate 40 includes a display area 41, and a flexible circuit board is bound along a first direction D1 near a lower edge of the display area 41, and the flexible circuit board 42 is fixed with a driving chip 43.

Specifically, the S10 further includes:

First, providing a TFT array substrate 40. The TFT array substrate 40 includes a display area 41, the TFT array substrate 40, the driving chip 43, and the flexible circuit board 42 are bound along a first direction D1 near a lower edge of the display area 41. The flexible circuit board 42 is bonded to the TFT array substrate 40 by an anisotropic conductive film, and the driving chip 43 is also bounded to the flexible circuit board 42 by the anisotropic conductive film.

Specifically, the anisotropic conductive film is a semi-transparent polymer splicing material having three major characteristics of adhesion, conductivity, and insulation, and can provide fine pitch, high reliability and cold interconnection. The anisotropic conductive film is characterized by electrical conduction in the longitudinal direction (Z direction) and high impedance characteristic in the lateral plane (X, Y direction). The main component of the anisotropic conductive film is a binder which is doped with a plurality of conductive particles and has a film thickness of about several tens of micrometers, and further includes a base film for protection. The conductive particles are nickel-plated and gold-plated plastic powder on the surface, with a plastic ball in the center and nickel-plated and gold-plated on the outside. The anisotropic conductive adhesive film can undergo hot pressing, that is, the anisotropic conductive adhesive film is cured by three factors of temperature, time, and pressure. The conductive particles are blasted to achieve a conductive effect, as illustrate in FIG. 4A.

S20, providing an electrostatic discharge circuit, wherein a plurality of pins of the driving chip are electrically connected to the electrostatic discharge circuit, the pins and the electrostatic discharge circuit form a closed loop.

Specifically, the S20 further includes:

The electrostatic discharge circuit 50 is composed of two or more shorting bars 51 and metal wires 52. A first end 511 of each of the shorting bars 51 is electrically connected to a corresponding one of the pins, and a second end 512 of each of the shorting bars 51 is electrically connected to the metal wires 52. The driving chip 43 is disposed along the first direction D1, the shorting bar 51 is disposed perpendicular to the first direction D1, and every two adjacent shorting bars 51 are provided with equal distance. Each of the pins includes a chip input pin and a chip output pin. The chip input pin is electrically connected to the corresponding one of the shorting bars 51. The chip output pin is electrically connected to the another corresponding one of the shorting bars 51. The pin on the driving chip 43 is electrically connected to the electrostatic discharge circuit 50, so that the pin and the electrostatic discharge circuit form a closed loop, as illustrated in FIG. 4B.

S30, providing a cutting line 60 enclosing a rectangular frame on the TFT array substrate 40, wherein the cutting line 60 passes through the electrostatic discharge circuit 50 along the first direction D1, and the TFT array substrate 40 is cut along the cutting line 60 using a cutter, and the electrostatic discharge circuit 50 is disconnected to obtain the antistatic display panel.

Specifically, the S30 further includes:

First, the cut line 60 enclosing a rectangular frame is disposed on the TFT array substrate 40, and the cut line 60 includes a first sub-cut line 61, a second sub-cut line 62, a third sub-cut line 63, and a four sub-cutting line 64, the first sub-cutting line 61 and the third sub-cut line 63 are arranged parallel along the first direction D1, the second sub-cut line 62 and the fourth sub-cutting line 64 are arranged in parallel along a direction perpendicular to the first direction D1. The third sub-cut line 63 passes through the shorting bars 51. Because during the cutting process, a large amount of static electricity is easily generated, and pins of the driving chip 43 are easy to attract static electricity. The pins conduct the attracted static electricity into the electrostatic discharge circuit 50, and when the panel is cut, the shorting bars 51 are disconnected with the adjacent pins to ensure subsequent modules normal use. Therefore, this effective protects the internal signal line of the narrow bezel display panel.

The antistatic display panel and the manufacturing method of the present disclosure can increase the electrostatic protection capability of the product when the edge of the frame is narrow.

The present disclosure has the beneficial effects that: the anti-static display panel and the manufacturing method provided by the present disclosure, providing a plurality of pins of the driving chip form a closed loop with the electrostatic discharge circuit, thereby effectively protecting the internal signal lines of the narrow bezel display panel. Further reducing the risk of electrostatic damage to the display panel, and improving product defect-free rate.

In summary, although the preferable embodiments of the present disclosure have been disclosed above. It should be noted that those of ordinary skill in the art can make a variety of improvements and substitutions on the premise of not deviating from the technical principle of the present disclosure, and these improvements and substitutions should be encompassed within the protection scope of the present disclosure.

What is claimed is:

1. An antistatic display panel, comprising:
a display area;
a flexible circuit board;
a driving chip; and
an electrostatic discharge circuit;
wherein the driving chip is fixed on a surface of the flexible circuit board and is bound near a lower edge of the display area; and
wherein a plurality of pins of the driving chip are electrically connected to the electrostatic discharge circuit, and the pins form a closed loop with the electrostatic discharge circuit.

2. The antistatic display panel as claimed in claim 1, wherein the electrostatic discharge circuit is composed of two or more shorting bars and metal wires.

3. The antistatic display panel as claimed in claim 2, wherein a first end of each of the shorting bars is electrically connected to a corresponding one of the pins, and a second end of each of the shorting bars is electrically connected to the metal wires.

4. The antistatic display panel as claimed in claim 2, wherein the driving chip is disposed along a first direction D1, each of the shorting bars is disposed perpendicular to the first direction D1, and every two adjacent shorting bars are provided with equal distance.

5. The antistatic display panel as claimed in claim 1, wherein each of the pins comprises a chip input pin and a chip output pin, the chip input pin is electrically connected to a corresponding one of the shorting bars, the chip output pin is electrically connected to another corresponding one of the shorting bars.

6. A method of manufacturing an antistatic display panel, comprising:
S10, providing a thin film transistor (TFT) array substrate, wherein the TFT array substrate comprises a display area, and a flexible circuit board is bound along a first direction D1 near a lower edge of the display area, and the flexible circuit board is fixed with a driving chip;
S20, providing an electrostatic discharge circuit, wherein a plurality of pins of the driving chip are electrically connected to the electrostatic discharge circuit, the pins and the electrostatic discharge circuit form a closed loop, and the electrostatic discharge circuit comprises two or more shorting bars and metal wires, the shorting bars are disposed perpendicular to the first direction D1, and every two adjacent shorting bars are provided with equal distance;
S30, providing a cutting line enclosing a rectangular frame on the TFT array substrate, wherein the cutting line passes through the electrostatic discharge circuit along the first direction D1, and the TFT array substrate is cut along the cutting line using a cutter, and the electrostatic discharge circuit is disconnected to obtain the antistatic display panel.

7. The method of manufacturing the antistatic display panel as claimed in claim 6, wherein a first end of each of the shorting bars is electrically connected to a corresponding one of the pins, and a second end of each of the shorting bars is electrically connected to the metal wires.

8. The method of manufacturing the antistatic display panel as claimed in claim 6, wherein in the S30, the cutting line comprises a first sub-cut line, a second sub-cut line, a third sub-cut line, and a fourth a sub-cut line, the first sub-cut line and the third sub-cut line are arranged in parallel along the first direction D1, and the second sub-cut line and the fourth sub-cut line are arranged in parallel along a direction perpendicular to the first direction D1.

9. The method of manufacturing the antistatic display panel as claimed in claim 8, wherein the third sub-cut line passes through the shorting bars.

10. A method of manufacturing the antistatic display panel, comprising:
S10, providing a TFT array substrate, the TFT array substrate comprises a display area, and a flexible circuit board is bound along a first direction D1 near a lower edge of the display area, and the flexible circuit board is fixed with a driving chip;
S20, providing an electrostatic discharge circuit, wherein a plurality of pins of the driving chip are electrically connected to the electrostatic discharge circuit, the pins and the electrostatic discharge circuit form a closed loop;
S30, providing a cutting line enclosing a rectangular frame on the TFT array substrate, wherein the cutting line passes through the electrostatic discharge circuit along the first direction D1, and the TFT array substrate is cut along the cutting line using a cutter, and the electrostatic discharge circuit is disconnected to obtain the antistatic display panel.

11. The method of manufacturing the antistatic display panel as claimed in claim 10, wherein in the S30, the cutting line comprises a first sub-cut line, a second sub-cut line, a third sub-cut line, and a fourth a sub-cut line, the first sub-cut line and the third sub-cut line are arranged in parallel along the first direction D1, and the second sub-cut line and the fourth sub-cut line are arranged in parallel along a direction perpendicular to the first direction D1.

12. The method of manufacturing the antistatic display panel as claimed in claim 10, wherein the third sub-cut line passes through the shorting bars.
